(19) United States
(12) Patent Application Publication
(10) Pub. No.: US 2023/0266258 A1
(43) Pub. Date: Aug. 24, 2023

(54) METHOD OF INSPECTING SEMICONDUCTOR DEVICE

(71) Applicant: Samsung Electronics Co., Ltd., Suwon-si (KR)

(72) Inventors: INHYE PARK, Seoul (KR); SUYOUNG LEE, Seongnam-si (KR); YUJIN CHO, Hwaseong-si (KR); JONG CHEON SUN, Seoul (KR); CHUNGSAM JUN, Suwon-si (KR)

(21) Appl. No.: 18/113,121

(22) Filed: Feb. 23, 2023

(30) Foreign Application Priority Data
Feb. 24, 2022 (KR) 10-2022-0024069

(51) Int. Cl. G01N 23/2251

(52) U.S. Cl. CPC G01N 23/2251; G01N 2223/6116; G01N 2223/646

(57) ABSTRACT

A method of inspecting a semiconductor device includes charging an inspection region of a semiconductor device using a charging electron beam, and scanning the inspection region using a scanning electron beam. The charging of the inspection region includes dividing the inspection region into a charging region and a non-charging region, and charging the charging region using the charging electron beam. The scanning of the inspection region includes irradiating the scanning electron beam to the inspection region, and detecting secondary electrons emitted from the inspection region by the scanning electron beam.

### CROSS-REFERENCE TO RELATED APPLICATIONS

This U.S. non-provisional patent application claims priority under 35 U.S.C. §119 to Korean Patent Application No. 10-2022-0024069, filed on Feb. 24, 2022, in the Korean Intellectual Property Office, the entire contents of which are hereby incorporated by reference.

### BACKGROUND OF THE INVENTION

The present disclosure relates to a method of inspecting a semiconductor device, and more particularly, to a method of inspecting a semiconductor device, which is capable of inspecting whether the semiconductor device is failed or not.

A semiconductor device may be manufactured by various processes. For example, the semiconductor device may be manufactured by a photolithography process, an etching process, a deposition process and a test process, which are performed on a wafer (e.g., a silicon wafer). Electrical failure of the semiconductor device may be measured in the test process of the semiconductor device. Electrons may be injected into the semiconductor device to test the semiconductor device. The semiconductor device in which the electrons are injected may be scanned to check whether the semiconductor device is electrically failed or not. A scanning electron microscope (SEM) may be used to test the semiconductor device.

### SUMMARY

Embodiments of the inventive concepts may provide a method of inspecting a semiconductor device, which is capable of detecting failure of each of inspection targets.

Embodiments of the inventive concepts may also provide a method of inspecting a semiconductor device, which is capable of making a quantitative analysis of failure.

Embodiments of the inventive concepts may also provide a method of inspecting a semiconductor device, which is capable of inspecting the semiconductor device while variously changing an inspection order.

Embodiments of the inventive concepts may also provide a method of inspecting a semiconductor device, which is capable of detecting failure by a specific method depending on a type of the failure.

Embodiments of the inventive concepts may also provide a method of inspecting a semiconductor device, which is capable of reducing an inspection time.

According to an aspect of the present invention, a method of inspecting a semiconductor device includes charging an inspection region of a semiconductor device using a charging electron beam, and scanning the inspection region using a scanning electron beam. The charging of the inspection region includes dividing the inspection region into a charging region and a non-charging region, and charging the charging region using the charging electron beam. The scanning of the inspection region includes irradiating the scanning electron beam to the inspection region, and detecting secondary electrons emitted from the inspection region by the scanning electron beam.

According to an aspect of the present invention, a method of inspecting a semiconductor device includes dividing an inspection region of a semiconductor device into a plurality of inspection targets including a plurality of first targets and a plurality of second targets, and irradiating a charging electron beam to the plurality of first targets, without irradiating the charging electron beam to the plurality of second targets, by using a scanning electron microscope (SEM). The plurality of first targets are arranged in a plurality of first columns spaced apart from each other in a second direction, each first column of the plurality of first columns extending in a first direction, different from the second direction, and including at least two first targets spaced apart from each other in the first direction. The plurality of second targets are arranged in a plurality of second columns spaced apart from each other in the second direction, each second column of the plurality of second columns extending in the first direction and including at least two second targets spaced apart from each other in the first direction. Each first column of the plurality of first column and each second column of the plurality of second columns are alternately arranged in the second direction.

According to an aspect of the present invention, a method of inspecting a semiconductor device includes irradiating a first electron beam to an inspection region of a semiconductor device, irradiating a second electron beam to the inspection region, detecting secondary electrons emitted from the inspection region by the second electron beam, and analyzing the inspection region using information on the detected secondary electrons. The inspection region comprises a plurality of inspection targets including a conductive material. The irradiating of the first electron beam to the inspection region includes irradiating the first electron beam to some inspection targets of the plurality of inspection targets, without irradiating the other inspection targets of the plurality of inspection targets.

### BRIEF DESCRIPTION OF THE DRAWINGS

FIG. 1 is a schematic view illustrating an apparatus for inspecting a semiconductor device, according to some embodiments of the inventive concepts.

FIG. 2 is a flow chart illustrating a method of inspecting a semiconductor device, according to some embodiments of the inventive concepts.

FIGS. 3 to 10 are views illustrating the method of inspecting a semiconductor device in the flow chart of FIG. 2.

FIG. 11 is a view illustrating a a voltage contrast (VC) image formed by the method of inspecting a semiconductor device, according to some embodiments of the inventive concepts.

FIG. 12 is a plan view illustrating a semiconductor device according to some embodiments of the inventive concepts.

FIG. 13 is a plan view illustrating a semiconductor device according to some embodiments of the inventive concepts.

FIG. 14 is a plan view illustrating a semiconductor device according to some embodiments of the inventive concepts.

FIG. 15 is a flow chart illustrating a method of inspecting a semiconductor device, according to some embodiments of the inventive concepts.

FIG. 16 is a plan view illustrating a semiconductor device according to some embodiments of the inventive concepts.

FIG. 17 is a plan view illustrating an order of irradiating an electron beam onto a semiconductor device according to some embodiments of the inventive concepts.

### DETAILED DESCRIPTION

Example embodiments of the inventive concepts will now be described more fully with reference to the accompanying drawings. Like reference numerals or designators in the drawings denote like elements or components.

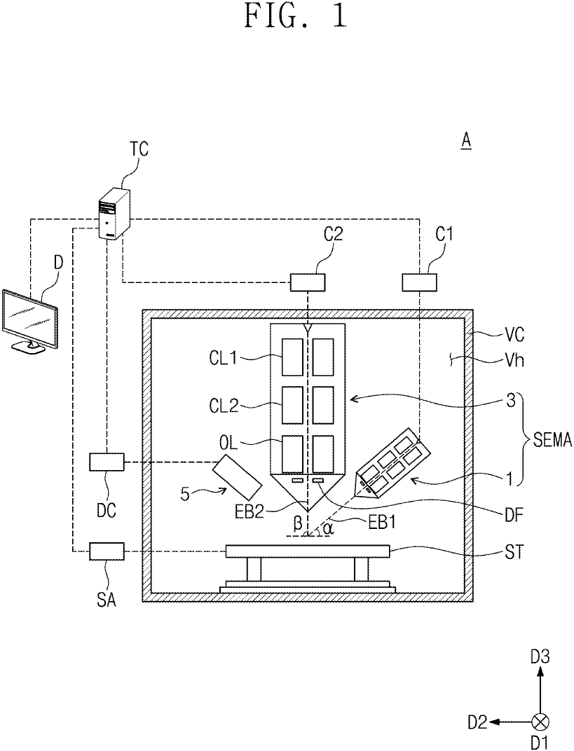

FIG. 1 is a schematic view illustrating an apparatus for inspecting a semiconductor device, according to some embodiments of the inventive concepts.

Hereinafter, a direction D1 of FIG. 1 may be referred to as a first direction, a direction D2 intersecting the first direction D1 may be referred to as a second direction, and a direction D3 intersecting both the first direction D1 and the second direction D2 may be referred to as a third direction. In an embodiment, the third direction D3 may be referred to as a vertical direction, and the first direction D1 and the second direction D2 may be referred to as horizontal directions.

Referring to FIG. 1, an apparatus A for inspecting a semiconductor device may be provided. The apparatus A for inspecting a semiconductor device may be an apparatus capable of detecting failure of a semiconductor device. More particularly, the apparatus A for inspecting a semiconductor device may detect electrical failure of an inspection target of a semiconductor device (e.g., an electrical short between two inspection targets). To achieve this, the apparatus A for inspecting a semiconductor device may include a vacuum chamber VC, a scanning electron microscope (SEM) assembly SEMA, a stage ST, a detector 5, a stage driving unit SA, a first SEM control unit C1, a second SEM control unit C2, a detector control unit DC, a total control unit TC, and a display D.

The vacuum chamber VC may provide an inspection space Vh. The inspection space Vh may be maintained in a vacuum state. For this, a vacuum pump (not shown) connected to the inspection space Vh may be provided. A semiconductor device may be disposed in the vacuum chamber VC. More particularly, the semiconductor device may be disposed on the stage ST in the vacuum chamber VC.

At least a portion of the SEM assembly SEMA may be located in the vacuum chamber VC. The SEM assembly SEMA may include a first SEM 1 and a second SEM 3.

The first SEM 1 may include a scanning electron microscope. The first SEM 1 may be a charging SEM. In other words, the semiconductor device on the stage ST may be charged (i.e., electrically charged, or positively or negatively charged) by the first SEM 1. More particularly, the first SEM 1 may irradiate a first electron beam EB1 toward the semiconductor device on the stage ST. The first SEM 1 may irradiate the first electron beam EB1 to the semiconductor device to charge a conductor (e.g., an electrode, etc.) in the semiconductor device. In other words, the first electron beam EB1 may be a charging electron beam. For example, the electrode in the semiconductor device, to which the first electron beam EB1 having a secondary electron yield greater than 1 is irradiated, may be charged with + charges (i.e., may be positively charged). The secondary electron yield refers to a number of emitted secondary electrons per a primary electron (e.g., an injected electron). In an embodiment, the electrode in the semiconductor device, to which the first electron beam EB1 having the secondary electron yield smaller than 1 is irradiated, may be charged with - charges (i.e., may be negatively charged). For this, the first SEM 1 may include a plurality of condenser lenses, an object lens, and a deflector. The first SEM 1 may form a first angle α with a top surface of the semiconductor device disposed on the stage ST. More particularly, the first SEM 1 may be disposed in such a way that the first electron beam EB1 irradiated by the first SEM 1 forms the first angle α with the top surface of the semiconductor device. A resolution of the first SEM 1 may be lower than a resolution of the second SEM 3.

The second SEM 3 may include a scanning electron microscope. The second SEM 3 may be spaced apart from the first SEM 1. The second SEM 3 may be a scanning SEM. In other words, the second SEM 3 may scan the semiconductor device on the stage ST. More particularly, the second SEM 3 may irradiate a second electron beam EB2 toward the semiconductor device on the stage ST. Thus, the electrode of the semiconductor device, which is charged by the first electron beam EB1, may be scanned by the second electron beam EB2 irradiated by the second SEM 3. In other words, the second electron beam EB2 may be a scanning electron beam. For this, the second SEM 3 may include a first condenser lens CL1, a second condenser lens CL2, an object lens OL, and a deflector DF. The deflector DF may control an irradiation angle of the second electron beam EB2. The second SEM 3 may form a second angle β with the top surface of the semiconductor device disposed on the stage ST. More particularly, the second SEM 3 may be disposed in such a way that the second electron beam EB2 irradiated by the second SEM 3 forms the second angle β with the top surface of the semiconductor device. The second angle β may be different from the first angle α. For example, the second angle β may be about 90 degrees, and the first angle α may be an acute angle. In a case in which the second angle β is a right angle, precision of the scanning may be improved. The first electron beam EB1 and the second electron beam EB2 may intersect each other at or under the top surface of the semiconductor device. The resolution of the second SEM 3 may be higher than the resolution of the first SEM 1. In an embodiment, the first electron beam EB1 (i.e., a charging electron beam) of the first SEM 1 and the second electron beam EB2 (i.e., a scanning electron beam) of the second SEM 3 may be directed toward the semiconductor device such that the first electron beam EB1 and the second electron beam EB2 may intersect each other at or under the top surface of the semiconductor device.

Two SEMs are illustrated and described in the above embodiments, but embodiments of the inventive concepts are not limited thereto. In certain embodiments, a single SEM may be provided. In this case, the charging electron beam and the scanning electron beam may be sequentially irradiated by the single SEM. More particularly, the single SEM may irradiate the first electron beam EB1 toward the semiconductor device and then may irradiate the second electron beam EB2 toward the semiconductor device. An angle between the electron beam irradiated by the single SEM and the top surface of the semiconductor device may be 90 degrees or may be an acute angle. However, hereinafter, the embodiments in which the two SEMs are provided will be described as an example for the purpose of ease and convenience in explanation.

The stage ST may be located under the SEM assembly SEMA. The stage ST may support the semiconductor device. The semiconductor device may be disposed on a top surface of the stage ST. The stage ST may include a chuck for fixing the semiconductor device. For example, the stage ST may include an electrostatic chuck (ESC) capable of fixing the semiconductor device by electrostatic force or a vacuum chuck capable of fixing the semiconductor device by a vacuum pressure. The stage ST may be movable with respect to the SEM assembly SEMA in a horizontal direction. Thus, the semiconductor device on the stage ST may also be movable with respect to the SEM assembly SEMA in the horizontal direction.

The detector 5 may detect secondary electrons and/or backscatter electrons, generated by an electron beam. For example, the detector 5 may detect secondary electrons ejected or emitted from the semiconductor device to which the second electron beam EB2 is irradiated. Information or data on the secondary electrons detected by the detector 5 may be transmitted to the total control unit TC.

The stage driving unit SA may move the stage ST. For example, the stage driving unit SA may move the stage ST, on which the semiconductor device is disposed, in a horizontal direction.

The first SEM control unit C1 may control the first SEM 1. For example, the first SEM control unit C1 may control the irradiation angle, the secondary electron yield and an irradiation time of the first electron beam EB1 irradiated by the first SEM 1.

The second SEM control unit C2 may control the second SEM 3. For example, the second SEM control unit C2 may control the irradiation angle, the secondary electron yield and an irradiation time of the second electron beam EB2 irradiated by the second SEM 3. More particularly, the second SEM control unit C2 may control the deflector DF to control the irradiation angle of the second electron beam EB2.

The detector control unit DC may control the detector 5. The detector control unit DC may transmit the information or data detected from the detector 5 to the total control unit TC. The total control unit TC may control the first SEM control unit C1, the second SEM control unit C2, the detector control unit DC, and the stage driving unit SA. The total control unit TC may form a voltage contrast image (VC image) by using the information or data on the secondary electrons, received from the detector 5. In an embodiment, the total control unit TC may form numerical data on the amount of the secondary electrons by using the information or data on the secondary electrons, received from the detector 5. In other words, the total control unit TC may form numerical data on an electrical signal by the secondary electrons, received from the detector 5. The display D may be connected to the total control unit TC. The display D may output the VC image formed by the total control unit TC. A user may observe the VC image outputted in the display D to check whether the semiconductor device is failed or not. This will be described later in more detail.

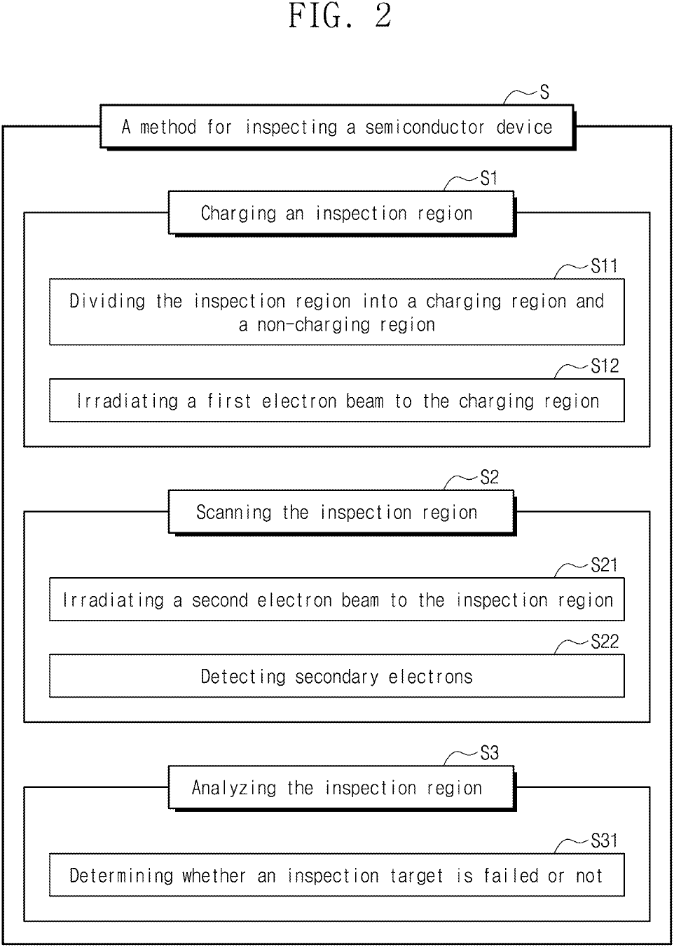

FIG. 2 is a flow chart illustrating a method of inspecting a semiconductor device, according to some embodiments of the inventive concepts.

Referring to FIG. 2, a method of inspecting a semiconductor device (S) may be provided. The method of inspecting a semiconductor device (S) may be a method of detecting failure of a semiconductor device by using the apparatus A for inspecting a semiconductor device, as described with reference to FIG. 1. The method of inspecting a semiconductor device (S) may include charging an inspection region (S1), scanning the inspection region (S2), and analyzing the inspection region (S3).

The charging of the inspection region (S1) may include dividing the inspection region into a charging region and a non-charging region (S11), and irradiating a first electron beam to the charging region (S12). In an embodiment, the charging of the inspection region (S1) may include irradiating the first electron beam to the charging region (S12), without irradiating the non-charging region (S11).

The scanning of the inspection region (S2) may include irradiating a second electron beam to the inspection region (S21), and detecting secondary electrons (S22).

The analyzing of the inspection region (S3) may include determining whether an inspection target is failed or not (S31).

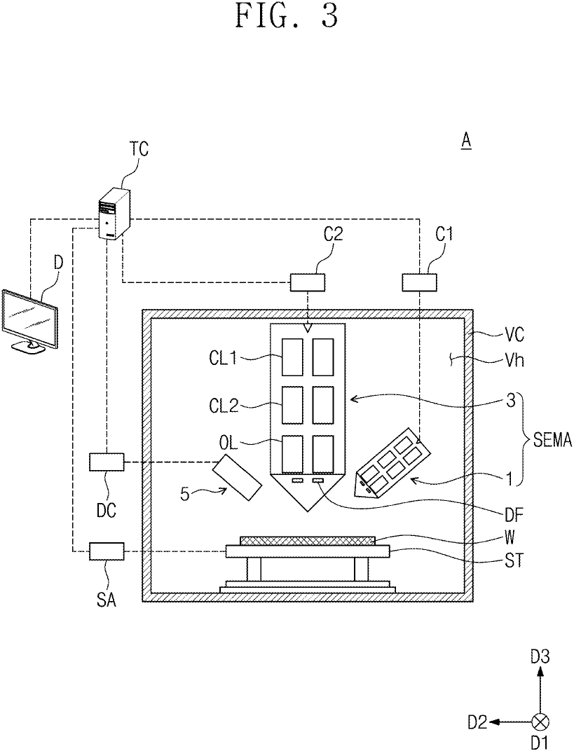

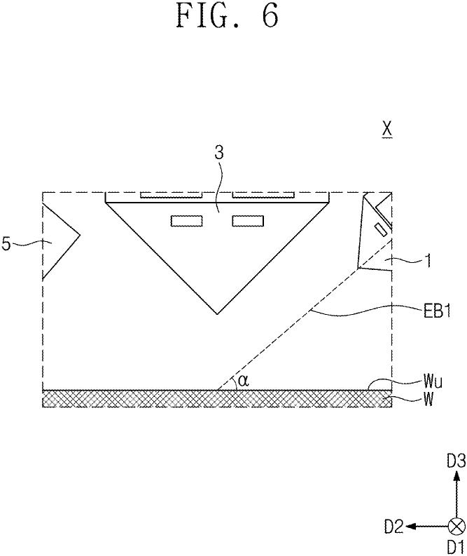

Hereinafter, the method of inspecting a semiconductor device in FIG. 2 will be described in detail with reference to FIGS. 3 to 11.

FIGS. 3 to 10 are views illustrating the method of inspecting a semiconductor device in the flow chart of FIG. 2.

Referring to FIG. 3, a semiconductor device W to be inspected may be disposed on the stage ST. The semiconductor device W may be a substrate in a wafer shape, on which an interconnection line, a transistor, etc. are formed. However, embodiments of the inventive concepts are not limited thereto, and in certain embodiments, the semiconductor device W loaded on the stage ST may have a chip shape. The semiconductor device W may be fixed on the stage ST. After the semiconductor device W is disposed on the stage ST, the inside of the vacuum chamber VC may be maintained in a vacuum state.

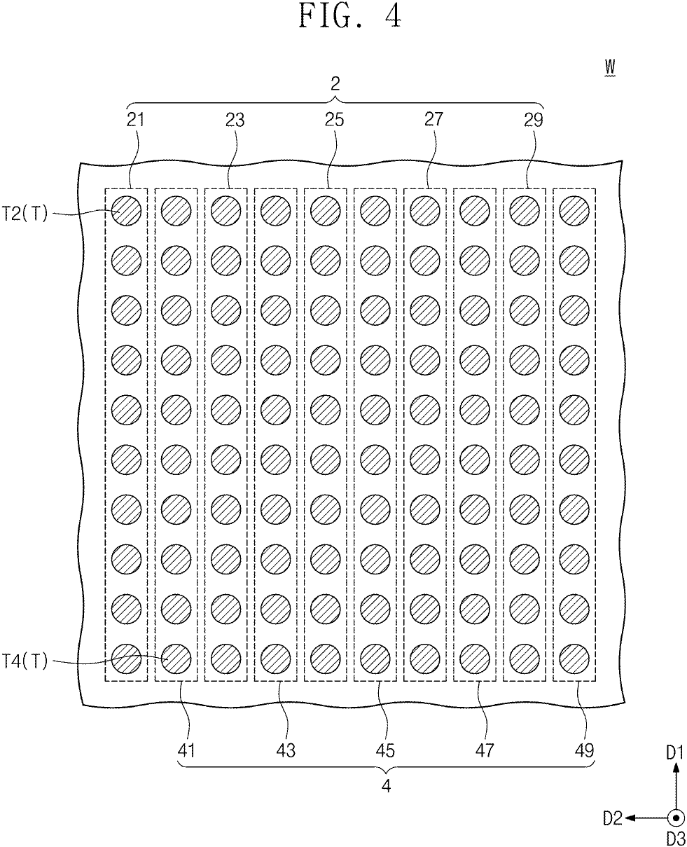

Referring to FIG. 4, the semiconductor device W may include an inspection target T. The inspection target T may be a target of which an electrical characteristic will be inspected. For example, the inspection target T may include a conductive material. More particularly, the inspection target T may include a capacitor of a DRAM device or a gate contact of a metal oxide semiconductor field effect transistor (MOSFET). However, embodiments of the inventive concepts are not limited thereto, and in certain embodiments, the inspection target T may include at least one of structures having other various shapes formed on the semiconductor device W. The inspection target T may be provided in plurality. The plurality of inspection targets T may be spaced apart from each other in a horizontal direction. For example, the plurality of inspection targets T may be spaced apart from each other in the first direction D1 and the second direction D2. However, the single inspection target T will be mainly described hereinafter for the purpose of ease and convenience in explanation.

Referring again to FIGS. 4 and 2, the dividing of the inspection region into the charging region and the non-charging region (S11) may include selecting a charging region 2 corresponding to a portion, necessary to be charged, of the inspection region. A region except the charging region 2 may be referred to as a non-charging region 4. Only the charging region 2 may be charged. In other words, the non-charging region 4 may not be charged. This will be described later in more detail.

The inspection target T in the charging region 2 may be referred to as a charging target T2. The charging target T2 may be provided in plurality. The plurality of charging targets T2 may be spaced apart from each other in the first direction D1. However, the single charging target T2 will be mainly described hereinafter for the purpose of ease and convenience in explanation.

The inspection target T in the non-charging region 4 may be referred to as a non-charging target T4. The non-charging target T4 may be provided in plurality. The plurality of non-charging targets T4 may be spaced apart from each other in the first direction D1. However, the single non-charging target T4 will be mainly described hereinafter for the purpose of ease and convenience in explanation.

In some embodiments, as illustrated in FIG. 4, the non-charging region 4 may be spaced apart from the charging region 2 in the second direction D2. Thus, the charging target T2 and the non-charging target T4 may be spaced apart from each other in the second direction D2.

The charging region 2 may be provided in plurality. For example, as shown in FIG. 4, the plurality of charging regions 21, 23, 25, 27 and 29 may be spaced apart from each other in the second direction D2. However, the single charging region 2 will be mainly described hereinafter for the purpose of ease and convenience in explanation.

The non-charging region 4 may be provided in plurality. For example, as shown in FIG. 4, the plurality of non-charging regions 41, 43, 45, 47 and 49 may be spaced apart from each other in the second direction D2. Each of the plurality of non-charging regions 41, 43, 45, 47 and 49 may be located between adjacent two of the plurality of charging regions 21, 23, 25, 27 and 29. Thus, the charging targets T2 and the non-charging targets T4 may be alternately arranged in the second direction D2. However, the single non-charging region 4 will be mainly described hereinafter for the purpose of ease and convenience in explanation.

In the dividing of the inspection region into the charging region and the non-charging region (S11), the charging region 2 and the non-charging region 4 may be divided by the total control unit TC and/or the first SEM control unit C1. The total control unit TC and/or the first SEM control unit C1 may store data for dividing the inspection region of the semiconductor device W. In other words, data for dividing the inspection region of the semiconductor device W into the charging region 2 and the non-charging region 4 may be stored in the total control unit TC and/or the first SEM control unit C1. In an embodiment, the data for dividing the inspection region may include coordinates of inspection targets to be inspected within a wafer or a chip. In an embodiment, the coordinates may be extracted from a layout semiconductor layout data (e.g., GDS data).

Referring to FIGS. 5, 6 and 2, the irradiating of the first electron beam to the charging region (S12) may include irradiating the first electron beam EB1 by the first SEM 1. The first SEM control unit C1 may control the first SEM 1 to adjust the secondary electron yield and/or the irradiation angle of the first electron beam EB1. The first electron beam EB1 may be irradiated to the semiconductor device W at the first angle α with respect to a top surface Wu of the semiconductor device W. When the first angle α is an acute angle, the first electron beam EB1 may be obliquely irradiated to the top surface Wu of the semiconductor device W.

Referring to FIGS. 7, 8 and 2, the irradiating of the first electron beam to the charging region (S12) may include irradiating the first electron beam EB1 to some of the plurality of inspection targets T. The first electron beam EB1 may not be irradiated to the others of the plurality of inspection targets T. More particularly, the first electron beam EB1 may be irradiated to only the plurality of charging targets T21, T23, T25, T27 and T29. The first electron beam EB1 may not be irradiated to the plurality of non-charging targets T4. Since the plurality of charging targets T2 and the plurality of non-charging targets T4 are alternately arranged in the second direction D2, the first electron beam EB1 may be irradiated while alternately skipping the inspection targets T in the second direction D2. In an embodiment, an inspection region may include a plurality of targets (i.e., a plurality of inspection targets). The plurality of targets may include a plurality of first targets (i.e., a plurality of charging targets 21, 23, 25, 27 and 29), and a plurality of second targets (i.e., a plurality of non-charging targets 41, 43, 45, 47, and 49). The plurality of first targets may be arranged in a plurality of first columns spaced apart from a second direction D2. Each first column may extend in a first direction D1, different from the second direction D2, and include at least two inspection targets spaced apart from each other in the first direction D1. The plurality of second targets may be arranged in a plurality of second columns spaced apart from each other in the second direction D2. Each second column may extend in the first direction D1 and include at least two inspection targets spaced apart from each other in the first direction D1. Each first column and each second column may be alternately arranged in the second direction D2. In an embodiment, the second direction D2 is perpendicular to the first direction D1.

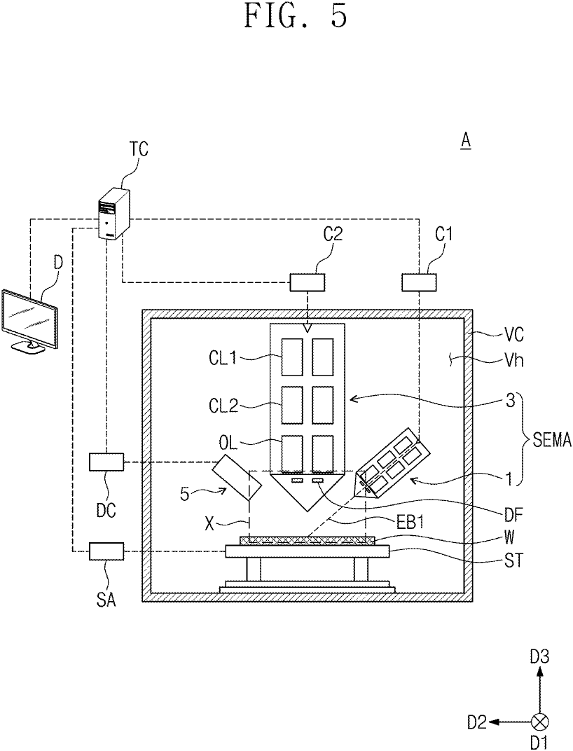

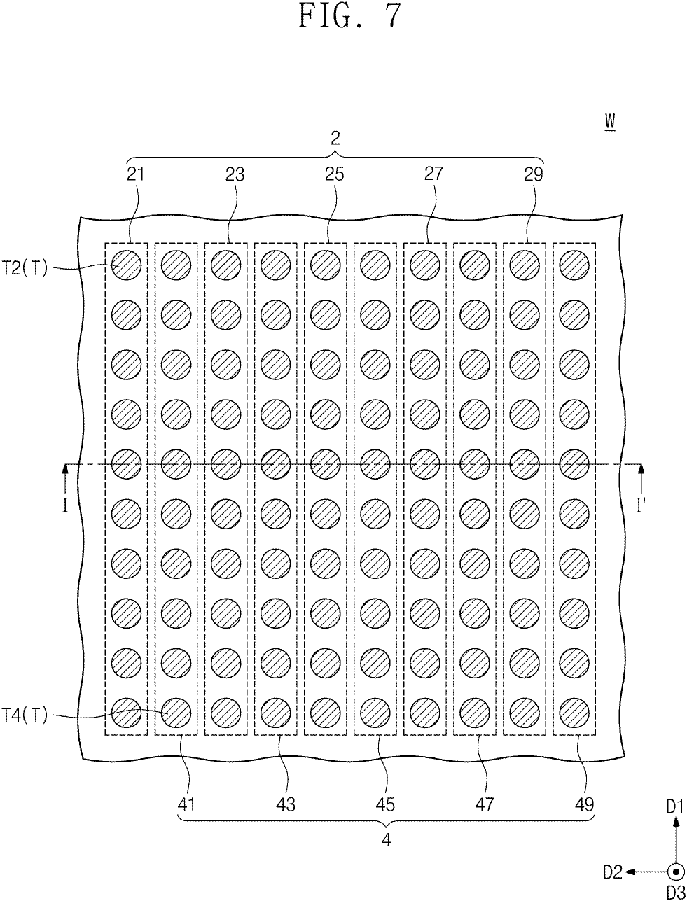

The irradiating of the first electron beam EB1 to the charging targets T2 may be sequentially performed. In other words, the first electron beam EB1 may be sequentially irradiated to the plurality of charging targets T2. In this process, the first SEM 1 may irradiate the first electron beam EB1 to the semiconductor device W while moving in the first direction D1 and/or the second direction D2 with respect to the semiconductor device W. For example, the first SEM 1 may move in a horizontal direction. In an embodiment, in a state in which the first SEM 1 is fixed at a certain position, the semiconductor device W may be moved in the horizontal direction by the stage driving unit SA (see FIG. 5). However, embodiments of the inventive concepts are not limited thereto, and in certain embodiments, the first electron beam EB1 may be irradiated to all of the plurality of charging targets T2 at once. In this case, a beam shaper (not shown) may be used. The beam shaper may allow the first electron beam EB1 irradiated onto the top surface Wu of the semiconductor device W to have the same shape as the charging region 2 (see FIG. 7).

Each of the plurality of charging targets T2 may be charged by the first electron beam EB1 irradiated by the first SEM 1. For example, when the secondary electron yield of the first electron beam EB1 is greater than 1, each of the plurality of charging targets T2 may be charged with + charges. At this time, the non-charging target T4 electrically insulated from the charging target T2 may not be charged. For the convenience of description, it is assumed that there is an electrical short between the charging target T25 and a non-charging target T45. In this case, the non-charging target T45 may be electrically connected to the charging target T25 of the plurality of charging targets T2, and the non-charging target T45 may be charged with + charges. More particularly, the charging target T25 of the plurality of charging targets T2 and/or the non-charging target T45 adjacent thereto may be bent to be electrically short with each other, and thus a leakage current may be generated therebetween. This charging target T2 may be referred to as a leakage charging target T25. In addition, this non-charging target T4 may be referred to as a leakage non-charging target T45. When the first electron beam EB1 is irradiated to the leakage charging target T25, electrons may move between the leakage charging target T25 and the leakage non-charging target T45. Thus, the leakage non-charging target T45 to which the first electron beam EB1 is not irradiated may also be charged. At this time, a charging degree of the leakage charging target T25 and/or the leakage non-charging target T45 may be weaker than a charging degree of other charging targets T21, T23, T27 and T29.

The irradiating of the first electron beam EB1 to the inspection region by using the first SEM 1 is illustrated and described in the above embodiments, but embodiments of the inventive concepts are not limited thereto. In certain embodiments, the charging target T2 may be charged using another component, not the SEM. For example, the charging target T2 may be charged using a conductive tip to electrically charge the charging target T2. For example, the conductive tip may be aligned to contact the charging target T2, and electrons may be supplied thereto via the conductive tip. The term “contact,” as used herein, refers to a direct connection (i.e., touching) unless the context indicates otherwise.

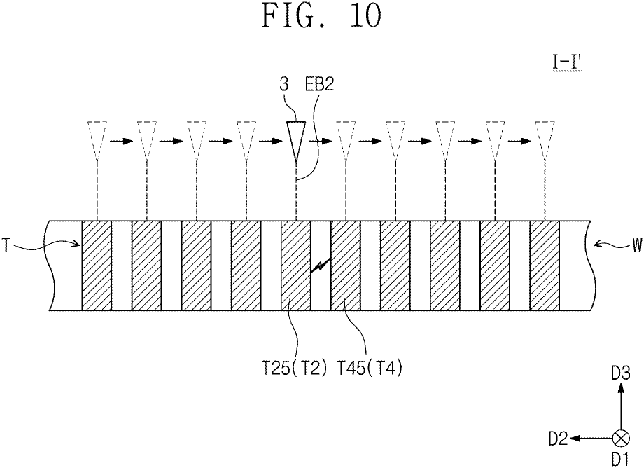

Referring to FIGS. 9 and 2, the irradiating of the second electron beam to the inspection region (S21) may include irradiating the second electron beam EB2 to the semiconductor device W by using the second SEM 3. As described above, an angle between the second electron beam EB2 irradiated by the second SEM 3 and the top surface Wu of the semiconductor device W may be the second angle β. The second angle β may be about 90 degrees. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

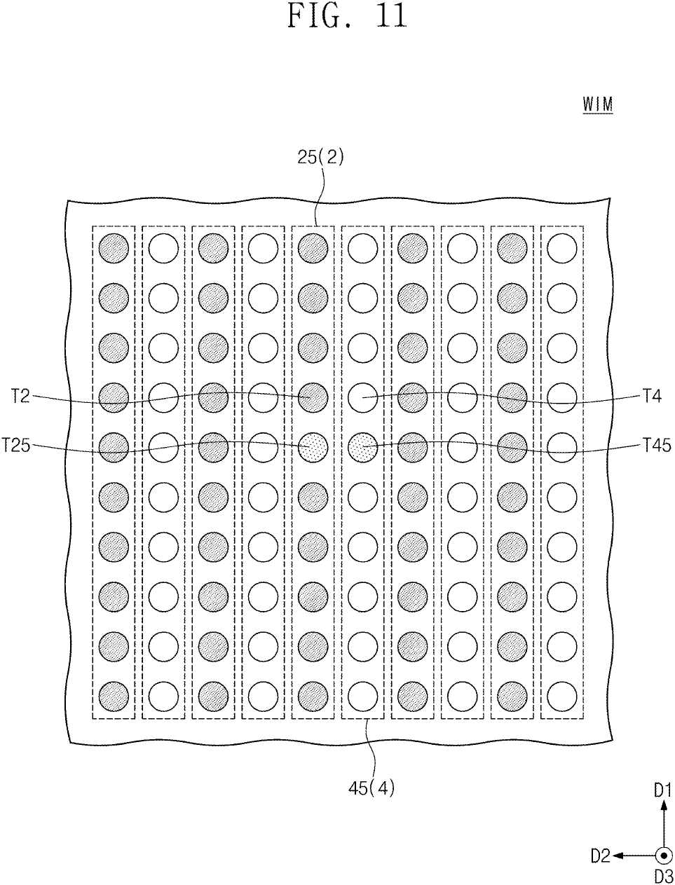

Referring to FIGS. 10 and 2, the irradiating of the second electron beam to the inspection region (S21) may include irradiating the second electron beam EB2 to each of the plurality of inspection targets T.

At this time, the second electron beam EB2 may be irradiated to all of the plurality of inspection targets T in the inspection region. In other words, the second electron beam EB2 may be irradiated to all of the charging target T2 and the non-charging target T4. More particularly, the second electron beam EB2 may be sequentially irradiated to the plurality of charging targets T2 and the plurality of non-charging targets T4.

In an embodiment, the second electron beam EB2 may be irradiated to only the charging target T2. In other words, the second electron beam EB2 may not be irradiated to the non-charging target T4. More particularly, the second electron beam EB2 may be sequentially irradiated to the plurality of charging targets T2.

The irradiating of the first electron beam and/or the irradiating of the second electron beam may be sequentially performed in a certain direction in the above embodiments, but embodiments of the inventive concepts are not limited thereto. In other words, an irradiating order of the electron beams to the plurality of inspection targets may be variously changed as needed.

Referring again to FIGS. 9 and 2, the detecting of the secondary electrons (S22) may include detecting secondary electrons SE by the detector 5. More particularly, the secondary electrons SE may be emitted from the semiconductor device W to which the second electron beam EB2 is irradiated. The secondary electrons SE emitted from the semiconductor device W may be detected by the detector 5. The amount of the emitted secondary electrons SE may be changed depending on a charging degree of the inspection target T (see FIG. 10) of the semiconductor device W. Information or data on the secondary electrons SE detected by the detector 5 may be transmitted to the detector control unit DC and/or the total control unit TC. The detector control unit DC and/or the total control unit TC may determine whether each of the plurality of inspection targets T is failed or not, by using the information or data on the secondary electrons SE.

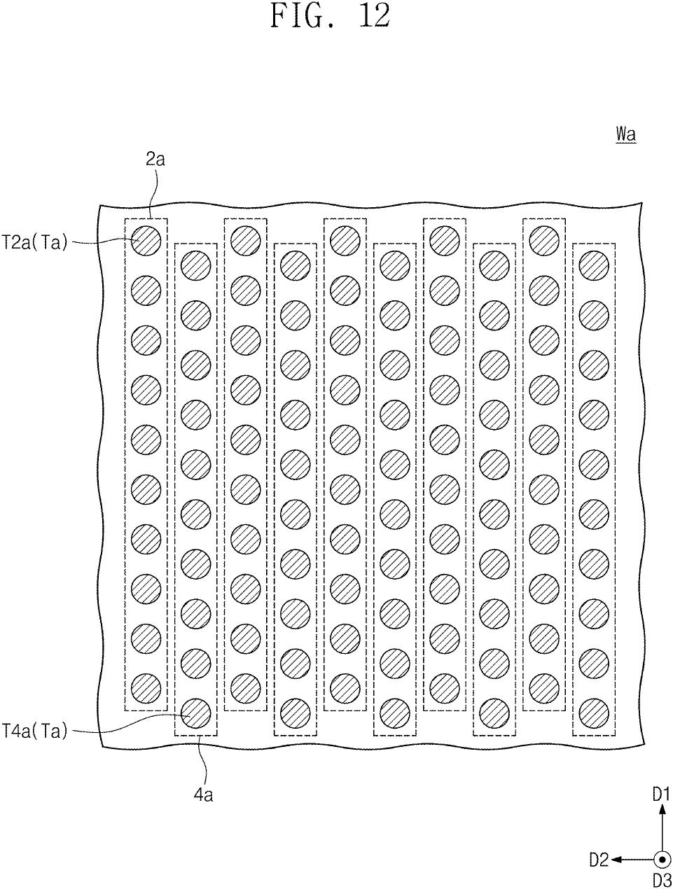

FIG. 11 is a view illustrating a VC image formed by the method of inspecting a semiconductor device, according to some embodiments of the inventive concepts.

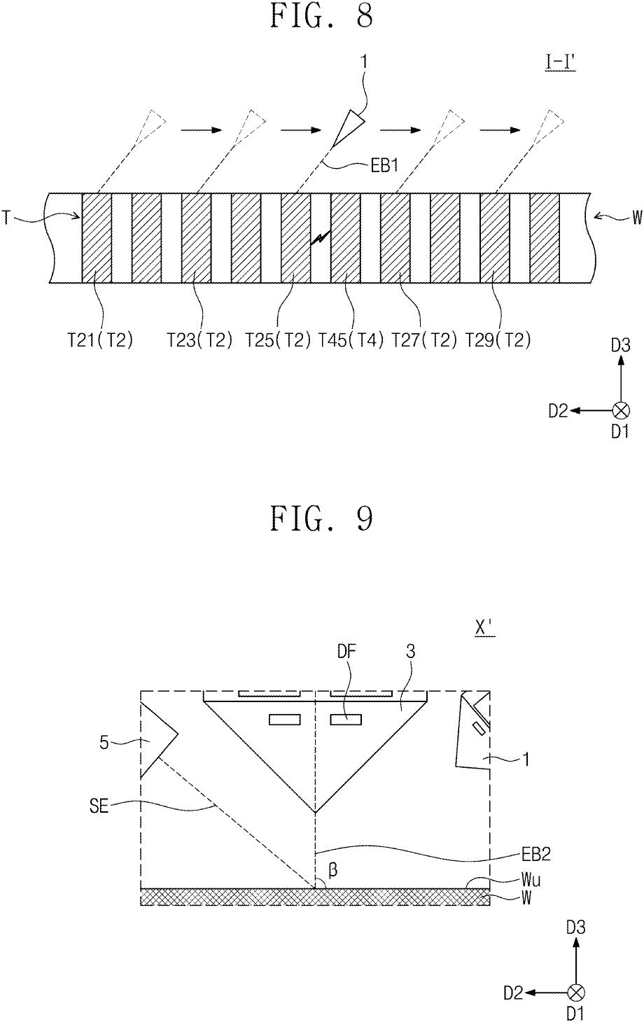

Referring to FIGS. 11 and 2, the determining whether the inspection target is failed or not (S31) may include determining whether each of the plurality of charging targets T2 (see FIG. 8) and each of the plurality of non-charging targets T4 (see FIG. 8) are failed or not.

At this time, the determining whether the inspection target is failed or not (S31) may include forming a VC image WIM of the inspection region.

In the VC image WIM, the charging target T2 sufficiently charged with + charges by the first electron beam EB1 (see FIG. 8) may be shown by a dark color. More particularly, since the charging target T2 is sufficiently charged with + charges, a small amount of the secondary electrons may be emitted when the second electron beam EB2 (see FIG. 10) is irradiated. Thus, the charging target T2 electrically insulated from the non-charging target T4 may be observed as the dark color in the VC image WIM.

On the contrary, in the VC image WIM, the non-charging target T4 not charged by the first electron beam EB1 may be shown by a bright color. More particularly, since the non-charging target T4 is not charged with + charges, a large amount of the secondary electrons may be emitted when the second electron beam EB2 is irradiated. Thus, the non-charging target T4 electrically insulated from the charging target T2 may be observed as the bright color in the VC image WIM.

The leakage charging target T25 and/or the leakage non-charging target T45 may be charged with a medium amount of + charges by the first electron beam EB1. When the second electron beam EB2 is irradiated to the leakage charging target T25 and/or the leakage non-charging target T45, a medium amount of the secondary electrons may be emitted. Thus, the leakage charging target T25 and/or the leakage non-charging target T45 may be observed as a medium color in the VC image WIM. The inspection target T observed as the medium color in the VC image WIM may be determined as failure. In other words, the inspection target T in which an electrical leakage is generated may be recognized.

In an embodiment, the determining whether the inspection target is failed or not (S31) may include forming numerical data on the amount of the secondary electrons emitted from the inspection region. In other words, the data on the amount of the emitted secondary electrons may be quantitatively represented to determine whether the inspection target is failed or not.

An electrical signal by the secondary electrons emitted from the charging target T2 (see FIG. 8) sufficiently charged with + charges may be relatively weak (i.e., a current of the electrical signal may be low). Thus, when a current by the secondary electrons emitted from the charging target T2 (i.e., a current of the electrical signal) is less than a certain value, the charging target T2 may not be failed. For example, when the electrical signal by the secondary electrons emitted from the charging target T2 is less than a second value, the charging target T2 may be normal. On the contrary, when the electrical signal by the secondary electrons emitted from the charging target T2 is equal to or greater than the second value, the charging target T2 may be determined as failure.

An electrical signal by the secondary electrons emitted from the non-charging target T4 (see FIG. 8) not charged with + charges may be relatively strong. Thus, when a current by the secondary electrons emitted from the non-charging target T4 is greater than a certain value, the non-charging target T4 may not be failed. For example, when the electrical signal by the secondary electrons emitted from the non-charging target T4 is greater than a first value, the non-charging target T4 may be normal. On the contrary, when the electrical signal by the secondary electrons emitted from the non-charging target T4 is equal to or less than the first value, the non-charging target T4 may be determined as failure. The first value may be greater than the second value.

In other words, when a current of an electrical signal by the secondary electrons emitted from any one of the inspection targets T is between the first value and the second value, this inspection target T may be determined as failure.

Failure or not of each of the inspection targets may be determined by the method of inspecting a semiconductor device according to the embodiments of the inventive concepts. At this time, the failure may be quantitatively analyzed, and thus a type of the failure may be identified. In an embodiment, an electrical failure such as electrical short may be quantitatively determined based on an amount of a current of an electrical signal generated from the secondary electrons. For example, an inspection target generating an electrical leakage with an adjacent inspection target may be detected.

The electron beam may be irradiated to only the inspection target necessary to be inspected in the method of inspecting a semiconductor device according to the embodiments of the inventive concepts, and thus an inspection time may be reduced.

Hereinafter, the descriptions to the same or similar features as mentioned with reference to FIGS. 1 to 11 will be omitted for the purpose of ease and convenience in explanation.

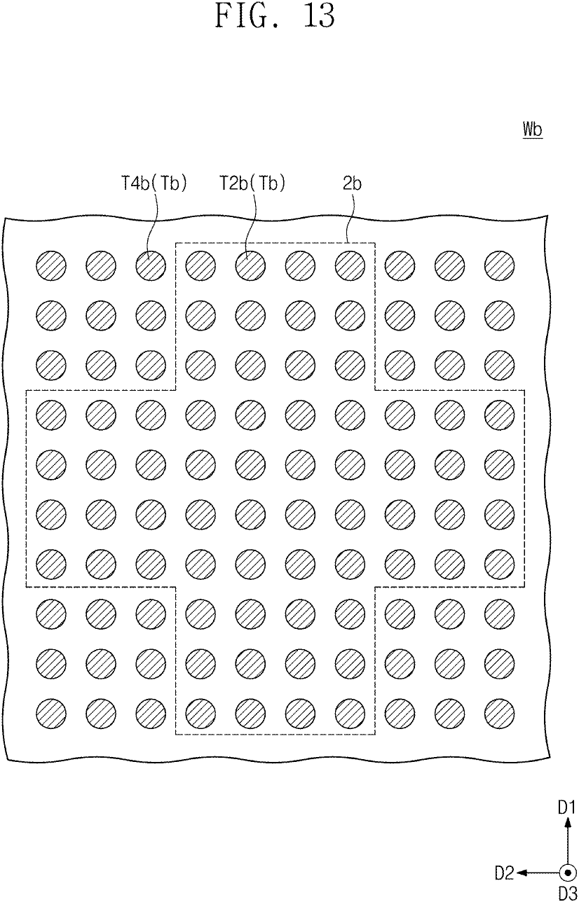

FIG. 12 is a plan view illustrating a semiconductor device according to some embodiments of the inventive concepts.

Referring to FIG. 12, an inspection region of a semiconductor device Wa may be divided into a charging region 2a and a non-charging region 4a. The charging region 2a may include a charging target T2a. The non-charging region 4a may include a non-charging target T4a. However, unlike the embodiments of FIG. 4, the charging target T2a and the non-charging target T4a may be offset from each other.

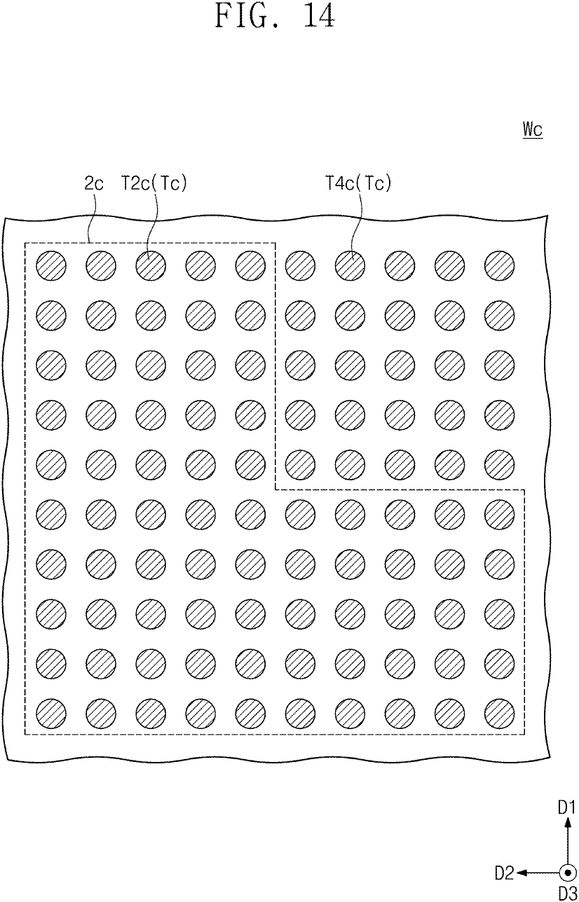

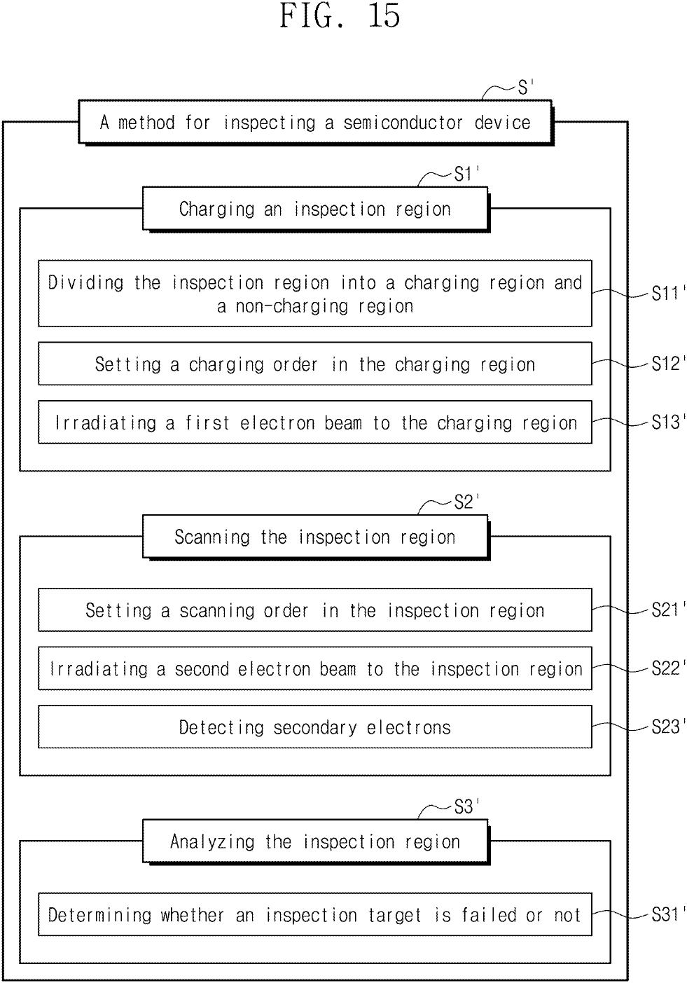

FIG. 13 is a plan view illustrating a semiconductor device according to some embodiments of the inventive concepts, and FIG. 14 is a plan view illustrating a semiconductor device according to some embodiments of the inventive concepts.

Referring to FIG. 13, an inspection region of a semiconductor device Wb may be divided into a charging region 2b and a remaining region. The charging region 2b may include a charging target T2b. An inspection target Tb of the remaining region may be a non-charging target T4b. However, unlike the embodiments of FIG. 4, a shape of the charging region 2b may not be a rectangular shape. For example, the charging region 2b may have a cross shape as a whole.

Referring to FIG. 14, an inspection region of a semiconductor device Wc may be divided into a charging region 2c and a remaining region. The charging region 2c may include a charging target T2c. An inspection target Tc of the remaining region may be a non-charging target T4c. However, unlike the embodiments of FIG. 4, a shape of the charging region 2c may not be a rectangular shape.

The charging regions having three shapes are illustrated in the above embodiments of FIGS. 4, 13 and 14, but embodiments of the inventive concepts are not limited thereto. In other words, the shape of the charging region may be variously changed as needed. To charge the charging targets in the charging regions having the various shapes, the first electron beam may be sequentially irradiated to the charging targets by using the first SEM. In an embodiment, the first electron beam may be irradiated to the charging targets in the charging region at once by using the beam shaper.

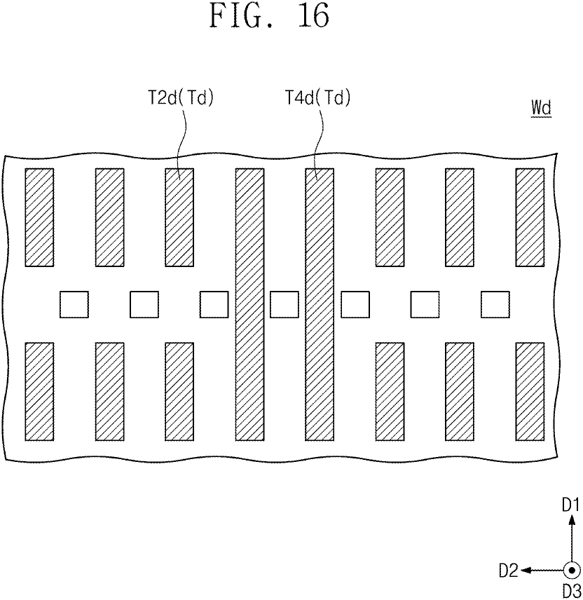

FIG. 15 is a flow chart illustrating a method of inspecting a semiconductor device, according to some embodiments of the inventive concepts.

Hereinafter, the descriptions to the same or similar features as mentioned with reference to FIGS. 1 to 14 will be omitted for the purpose of ease and convenience in explanation.

Referring to FIG. 15, a method of inspecting a semiconductor device (S′) may be provided. The method of inspecting a semiconductor device (S′) may include charging an inspection region (S1′), scanning the inspection region (S2′), and analyzing the inspection region (S3′).

Unlike the embodiments of FIG. 2, the charging of the inspection region (S1′) may further include setting a charging order in the charging region (S12′).

Unlike the embodiments of FIG. 2, the scanning of the inspection region (S2′) may further include setting a scanning order in the inspection region (S21′).

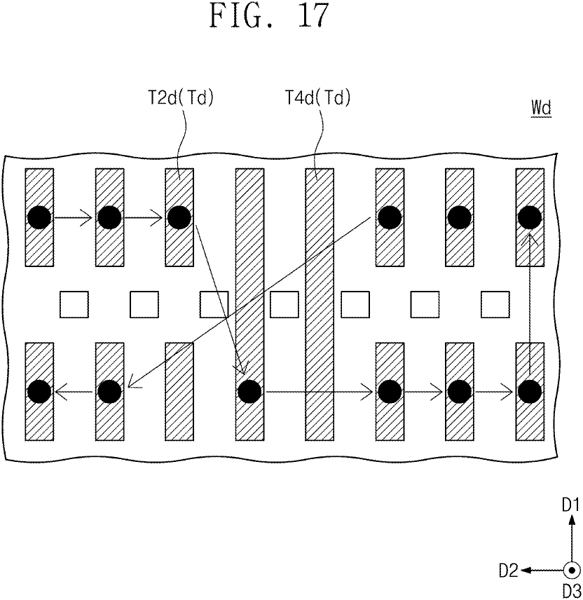

Hereinafter, the method of inspecting a semiconductor device in FIG. 15 will be described in detail with reference to FIGS. 16 and 17.

FIG. 16 is a plan view illustrating a semiconductor device according to some embodiments of the inventive concepts, and FIG. 17 is a plan view illustrating an order of irradiating an electron beam onto a semiconductor device according to some embodiments of the inventive concepts.

Referring to FIGS. 16, 17 and 15, the setting of the charging order in the charging region (S12′) may include setting a charging order of a plurality of charging targets T2d. The charging order may be set by various methods. For example, the charging order may be set with reference to semiconductor layout data (e.g., GDS data). In other words, the charging order of the plurality of charging targets T2d in a semiconductor device Wd may be set using the semiconductor layout data and the apparatus A for inspecting a semiconductor device (see FIG. 1). For example, a source contact and/or a drain contact of the plurality of charging targets T2d in the semiconductor device Wd may be first charged. Thereafter, a gate contact of the plurality of charging targets T2d may be charged. In an embodiment, a charging target T2d, having a specific size, of the plurality of charging targets T2d may be first charged. However, embodiments of the inventive concepts are not limited thereto, and the charging order of the plurality of charging targets T2d may be set by other various methods. The setting of the scanning order in the inspection region (S21′) may be performed by a similar method to the above methods of the setting of the charging order in the charging region (S12′).

In the method of inspecting a semiconductor device according to the embodiments of the inventive concepts, a semiconductor device may be inspected by changing the charging order and/or the scanning order of a plurality of inspection targets. In particular, an inspection order of the plurality of inspection targets may be set using the semiconductor layout data. Thus, inspections optimized for generable various failure types may be performed.

According to the method of inspecting a semiconductor device of the inventive concepts, failure or not of each of the inspection targets may be detected.

According to the method of inspecting a semiconductor device of the inventive concepts, the quantitative analysis of failure may be performed.

According to the method of inspecting a semiconductor device of the inventive concepts, the inspection targets may be inspected while variously changing the inspection order of the inspection targets.

According to the method of inspecting a semiconductor device of the inventive concepts, failure may be detected by a method optimized for the type of failure.

According to the method of inspecting a semiconductor device of the inventive concepts, the inspection time may be reduced.

While example embodiments of the inventive concepts have been particularly shown and described, it will be understood by one of ordinary skill in the art that variations in form and detail may be made therein without departing from the spirit and scope of the attached claims.

What is claimed is:

1. A method of inspecting a semiconductor device, the method comprising:
charging an inspection region of a semiconductor device using a charging electron beam; and
scanning the inspection region using a scanning electron beam,
wherein the charging of the inspection region comprises:
dividing the inspection region into a charging region and a non-charging region; and
charging the charging region using the charging electron beam, and
wherein the scanning of the inspection region comprises:
irradiating the scanning electron beam to the inspection region; and
detecting secondary electrons emitted from the inspection region by the scanning electron beam.

2. The method of claim 1,
wherein the charging of the charging region comprises:
irradiating the charging electron beam to the charging region.

3. The method of claim 2,
wherein the charging region comprises a plurality of charging targets, and
wherein the irradiating of the charging electron beam to the charging region comprises:
sequentially irradiating the charging electron beam to the plurality of charging targets.

4. The method of claim 1,
wherein the charging region comprises a plurality of charging targets, and
wherein the non-charging region comprises a plurality of non-charging targets.

5. The method of claim 4,
wherein the irradiating of the scanning electron beam to the inspection region comprises:
sequentially irradiating the scanning electron beam to the plurality of charging targets and the plurality of non-charging targets.

6. The method of claim 4,
wherein the irradiating of the scanning electron beam to the inspection region comprises:
sequentially irradiating the scanning electron beam to the plurality of charging targets.

7. The method of claim 4, further comprising:
analyzing the inspection region using information on the detected secondary electrons,
wherein the analyzing of the inspection region comprises:
determining whether each charging target of the plurality of charging targets and each non-charging target of the plurality of non-charging targets is failed or not.

8. The method of claim 7,
wherein the analyzing of the inspection region comprises:
forming at least one of a voltage contrast (VC) image of the inspection region and numerical data on an amount of a current of the detected secondary electrons.

9. The method of claim 4,
wherein the plurality of charging targets are arranged in a first direction,
wherein the plurality of non-charging targets are arranged in the first direction, and
wherein the plurality of charging targets are spaced apart from the plurality of non-charging targets in a second direction intersecting the first direction.

10. A method of inspecting a semiconductor device, the method comprising:
dividing an inspection region of a semiconductor device into a plurality of inspection targets including a plurality of first targets and a plurality of second targets; and irradiating a charging electron beam to the plurality of first targets, without irradiating the charging electron beam to the plurality of second targets, by using a scanning electron microscope (SEM),
wherein the plurality of first targets are arranged in a plurality of first columns spaced apart from each other in a second direction, each first column of the plurality of first columns extending in a first direction, different from the second direction, and including at least two first targets spaced apart from each other in the first direction,
wherein the plurality of second targets are arranged in a plurality of second columns spaced apart from each other in the second direction, each second column of the plurality of second columns extending in the first direction and including at least two second targets spaced apart from each other in the first direction, and wherein each first column of the plurality of first column and each second column of the plurality of second columns are alternately arranged in the second direction.

11. The method of claim 10,
wherein the SEM sequentially irradiates the charging electron beam to the plurality of charging targets while moving in the first direction and the second direction with respect to the semiconductor device.

12. The method of claim 10, further comprising:
irradiating a scanning electron beam to the plurality of inspection targets; and
detecting secondary electrons emitted from the plurality of inspection targets by the scanning electron beam.

13. The method of claim 12, further comprising:
analyzing the inspection region using information on the detected secondary electrons,
wherein the analyzing of the inspection region comprises:
determining whether each of the plurality of inspection targets is failed or not.

14. The method of claim 13,
wherein the determining whether each of the plurality of inspection targets is failed or not comprises:
determining whether one of the plurality of first targets is electrically short with one of the plurality of second targets.

15. The method of claim 14,
wherein the determining whether each of the plurality of inspection targets is failed or not comprises:
determining an amount of a current of an electrical signal by secondary electrons emitted from one of the plurality of second targets is equal to or less than a first value.

16. The method of claim 15,
wherein the determining whether each of the plurality of inspection targets is failed or not comprises:
determining an amount of a current of an electrical signal by secondary electrons emitted from one of the plurality of first targets is equal to or greater than a second value, and
wherein the second value is less than the first value.

17. A method of inspecting a semiconductor device, the method comprising: irradiating a first electron beam to an inspection region of a semiconductor device; irradiating a second electron beam to the inspection region; detecting secondary electrons emitted from the inspection region by the second electron beam; and
analyzing the inspection region using information on the detected secondary electrons, wherein the inspection region comprises a plurality of inspection targets including a conductive material, and
wherein in the irradiating of the first electron beam to the inspection region includes:
irradiating the first electron beam to some inspection targets of the plurality of inspection targets, without irradiating the other inspection targets of the plurality of inspection targets.

18. The method of claim 17,
wherein some inspection targets are arranged in a plurality of first columns spaced apart from each other in a second direction, each first column extending in a first direction, different from the second direction, and including at least two inspection targets, spaced apart from each other in the first direction, of the plurality of inspection targets,
wherein other inspection targets are arranged in a plurality of second columns spaced apart from each other in the second direction, each second column extending in the first direction and including at least two inspection targets, spaced apart from each other in the first direction, of the plurality of inspection targets,
wherein each first column of the plurality of first column and each second column of the plurality of second columns are alternately arranged in the second direction, and
wherein the irradiating of the first electron beam to the inspection region comprises:
irradiating the first electron beam to inspection targets of the plurality of first columns, without irradiating the first electron beam to inspection targets of the plurality of second columns.

19. The method of claim 17,
wherein the analyzing of the inspection region comprises:
determining whether each of the inspection targets is failed or not.

20. The method of claim 19,
wherein the determining whether each of the inspection targets is failed or not comprises:
determining each of the plurality of inspection targets as failure when a current of an electrical signal by secondary electrons detected from each inspection target of the plurality of inspection targets is between a first value and a second value.
